(19) United States
(12) Patent Application Publication
(10) Pub. No.: US 2021/0035776 A1
(43) Pub. Date: Feb. 4, 2021

(54) PLASMA PROCESSING DEVICE MEMBER AND PLASMA PROCESSING DEVICE

(71) Applicant: KYOCERA Corporation, Kyoto-shi, Kyoto (JP)

(72) Inventor: Manpei TANAKA, Higashiomi-shi, Shiga (JP)

(21) Appl. No.: 16/650,755

(22) PCT Filed: Sep. 28, 2018
(86) PCT No.: PCT/JP2018/036464

§ 371 Date: Mar. 25, 2020

(30) Foreign Application Priority Data
Sep. 28, 2017 (JP) 2017-187886

(51) Int. Cl. H01J 37/32; C01F 17/218; H01L 21/67

(52) U.S. Cl. CPC H01J 37/3244; C01F 17/218; H01L 21/67069; H01J 2237/334; C01P 2002/60; C01P 2006/80; C01P 2006/16

(57) ABSTRACT

A plasma processing device member of the present disclosure is made of an yttrium oxide sintered body containing 98% by mass or more of yttrium oxide and having a plurality of open pores, in which when an average of the distances between centers of gravity of the open pores adjacent to each other is set to L1, L1 is 50 μm or more. Additionally, a plasma processing device of the present disclosure includes the plasma processing device member and a plasma generator.

### TECHNICAL FIELD

The present disclosure relates to a plasma processing device member and a plasma processing device.

### BACKGROUND ART

Plasma processing devices are used to manufacture semiconductors and liquid crystal display devices. Plasma processing device members that are to be used in the plasma processing devices are exposed to plasma, and therefore a high corrosion resistance is required.

Ceramics have a higher corrosion resistance than metals and the like. Among them, yttrium oxide has an excellent corrosion resistance, and therefore an yttrium oxide sintered body is used in a portion exposed to plasma.

In the case where an yttrium oxide sintered body is used as a plasma processing device member, an open pore becomes the starting point of corrosion, and thus it is particularly required to eliminate open pores.

However, it has been difficult to eliminate open pores of an yttrium oxide sintered body produced by using, as a raw material, yttrium oxide powder that is a difficult-to-sinter material.

For example, Patent Document 1 (International Publication No. 2008/088071) describes that boron is added as an auxiliary agent that promotes sintering by forming a liquid phase at a temperature of 1100 to 1600° C., so that the crystal grain size of a sintered body is reduced and the amount of closed pores is reduced, and further describes when 0.02 to 5 wt % of boron is added, the open porosity determined by the Archimedes method is 0.05 to 0.24%.

It is difficult to eliminate open pores of an yttrium oxide sintered body even if a sintering aid that forms a liquid phase at a relatively low temperature, such as boron, is used as described in Patent Document 1. Open pores exist and the distance between the open pores is less than 10μm, according to FIG. 1 of Patent Document 1. When the distance between open pores is small as described above, it is difficult to obtain a sufficient corrosion resistance, and a further improvement in corrosion resistance is required.

### SUMMARY OF THE INVENTION

A plasma processing device member according to the present disclosure is made of an yttrium oxide sintered body that contains 98% by mass or more of yttrium oxide and has a plurality of open pores, in which when an average of distances between centers of gravity of the open pores adjacent to each other is set to L1, L1 is 50μm or more.

Moreover, a plasma processing device according to the present disclosure includes the above plasma processing device member and a plasma generator.

### BRIEF DESCRIPTION OF THE DRAWINGS

FIG. 1 shows part of a plasma processing device including an upper electrode in which a gas passage pipe serving as a plasma processing device member of the present disclosure is installed, of which (a) is a cross-sectional view and (b) is an enlarged view of the A portion of (a).

### EMBODIMENTS FOR CARRYING OUT THE INVENTION

Hereinafter, a plasma processing device member and a plasma processing device according to the present disclosure will be described in detail with reference to the drawing.

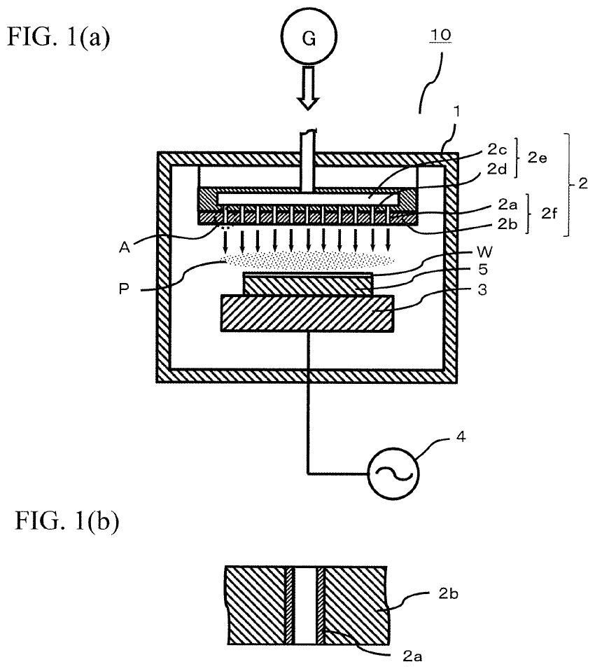

FIG. 1 shows part of a plasma processing device including an upper electrode in which a gas passage pipe serving as a plasma processing device member of the present disclosure is installed, of which (a) is a cross-sectional view and (b) is an enlarged view of the A portion of (a).

A plasma processing device 10 of the present disclosure shown in FIG. 1 is, for example, a plasma etching apparatus, and includes a chamber 1 in which a processing target member W such as a semiconductor wafer is arranged. An upper electrode 2 is arranged in an upper portion of the chamber 1, and a lower electrode 3 is arranged in a lower portion so as to face each other.

The upper electrode 2 includes: an electrode plate 2b on which a number of gas passage pipes 2a for supplying a plasma generating gas G into the chamber 1 are mounted; and a holding member 2e having in it a diffusion portion 2c that is an internal space for diffusing the plasma generating gas G and a number of introduction holes 2d for introducing the diffused plasma generating gas G into the gas passage pipes 2a.

The plasma generating gas G discharged in a shower form from the gas passage pipes 2a becomes plasma by supplying high-frequency power from a high-frequency power supply 4, so that a plasma space P is formed. The electrode plate 2b and the gas passage pipes 2a may be collectively referred to as a shower plate 2f.

Since the gas passage pipes 2a are small, their positions are only shown in FIG. 1(a), and the detailed configuration is shown in FIG. 1(b).

Of these members, for example, the upper electrode 2, the lower electrode 3, and the high-frequency power supply 4 constitute a plasma generator.

Herein, examples of the plasma generating gas G include: fluorine-containing gases such as SF₆, CF₄, CHF₃, ClF₃, NF₃, C₄F₈, and HF; and chlorine-containing gases such as Cl₂, HCl, BCl₃, and CCl₄. The gas passage pipe 2a is one example of the plasma processing device member. Hereinafter, it may be referred to as a plasma processing device member 2a.

The lower electrode 3 is a susceptor made of, for example, aluminum, and an electrostatic chuck 5 is placed on the susceptor, so that the processing target member W is held by electrostatic adsorption force.

Then, the coating film formed on the surface of the processing target member W is etched by ions and radicals contained in plasma.

The gas passage pipe 2a, which is the plasma processing device member 2a of the present disclosure, is made of, for example, a cylindrical yttrium oxide ceramic sintered body, and the inner peripheral surface and the discharge side end surface thereof are exposed to the plasma generating gas G.

The plasma processing device member 2a of the present disclosure is made of an yttrium oxide sintered body that contains 98% by mass or more of yttrium oxide having a high corrosion resistance to the plasma generating gas G, and that has a plurality of open pores, and when the average of the distances between the centers of gravity of the adjacent open pores is set to L1, L1 is 50μm or more.

Yttrium oxide is a material having a high corrosion resistance to the plasma generating gas G. The yttrium oxide sintered body constituting the plasma processing device member 2a of the present disclosure has a higher corrosion resistance as the content of yttrium oxide is higher. In particular, the content of yttrium oxide may be 99.0% by mass or more, 99.5% by mass or more, or further 99.9% by mass or more.

In addition to yttrium oxide, at least one element of, for example, silicon, iron, aluminum, calcium, and magnesium may be contained in which: the content of silicon may be 300 ppm by mass or less in terms of SiO₂; the content of iron may be 50 ppm by mass or less in terms of Fe₂O₃; the content of aluminum may be 100 ppm by mass or less in terms of Al₂O₃; and the contents of calcium and magnesium may be 350 ppm by mass or less in total in terms of CaO and MgO, respectively. The content of carbon may be 100 ppm by mass or less.

The presence of yttrium oxide can be identified and confirmed by an X-ray diffractometer using CuKα rays, and the content of each component may be determined by, for example, an ICP (Inductively Coupled Plasma) emission spectrometer or a fluorescent X-ray analyzer. The content of carbon may be determined by using a carbon analyzer.

In an yttrium oxide sintered body, it is known that when the number of open pores increases, the corrosion resistance deteriorates. However, it is difficult to completely eliminate open pores from an yttrium oxide sintered body.

The present applicant has found that even in an yttrium oxide sintered body having a plurality of open pores, its corrosion resistance is improved by making L1, which is set to the average of the distances between the centers of gravity of the adjacent open pores, equal to or more than 50μm, thereby completing the present invention.

In the plasma processing device member 2a of the present disclosure, which is made of an yttrium oxide sintered body having L1 of 50μm or more, even if particles are generated from the open pores when the plasma generating gas G contacts the surface of the yttrium oxide sintered body, the fear that the particles may collide with the outlines (edges) of the adjacent open pores is reduced since L1 is relatively large, whereby new particles are less likely to be generated.

In determining the average of the distances between the centers of gravity of the open pores, an area of the surface of the sintered body, having, for example, 1.1 mm of horizontal length and 0.8 mm of vertical length, is observed by using an optical microscope at a magnification of 100 times.

With the area being a measurement target, the distance between the centers of gravity of the adjacent open pores can be determined by applying a method called the center-of-gravity distance method of the image analysis software “A Image-kun (Ver2.52)” (registered trademark, manufactured by Asahi Kasei Engineering Corporation). Herein, the distance between the centers of gravity of the open pores in the present disclosure means the length of a straight line connecting the centers of gravity of the open pores.

The measurement conditions are ones in which, as setting conditions for the center-of-gravity distance method, the brightness of particles is set to dark, the binarization method to manual, the threshold to 190 to 220, the small figure removal area to 0.5μm², and the noise reduction filter to inclusion.

In the above measurement, the threshold is set to 190 to 220, but the threshold may be adjusted according to the brightness of an image in the area. After the brightness of particles is set to dark, the binarization method to manual, the small figure removal area to 0.5μm², and the noise reduction filter to inclusion, the threshold may be adjusted such that the marker appearing in the image matches the shape of the open pore.

Additionally, the kurtosis of the distances between the centers of gravity of the open pores may be 0 or more.

When the kurtosis of the distances between the centers of gravity of the open pores is within this range, a variation in the distance between the centers of gravity of the open pores is small, and many of the distances between the centers of gravity of the open pores show values close to the average; and hence particles are further less likely to be generated, and the probability of suppressing the extension of microcracks is further increased, thereby improving reliability.

It is particularly preferable that the kurtosis of the distances between the centers of gravity of the open pores is 0.05 or more.

In the plasma processing device member 2a of the present disclosure, the average of the diameters of the open pores may be 2.5μm or less. When the average of the diameters of the open pores is 2.5μm or less, particles are less likely to enter the open pores. When particles are less likely to enter the open pores, the possibility that the wall surfaces of the open pores may be damaged and new particles may be generated is reduced.

Additionally, the kurtosis of the diameters of the open pores may be 0 or more.

When the kurtosis of the diameters of the open pores is within this range, the number of open pores having an abnormally large diameter is reduced, so particles generated from the insides of the open pores can be relatively reduced.

It is particularly preferable that the kurtosis of the distances between the centers of gravity of the open pores is 0.5 or more.

Herein, a kurtosis Ku is an index (statistic) indicating how different the peak and tail of a distribution are from a normal distribution, and when the kurtosis Ku>0, the distribution has a sharp peak; when the kurtosis Ku=0, the distribution is a normal distribution; and when the kurtosis Ku<0, the distribution has a rounded peak.

Additionally, the coefficient of variation in the diameters of the open pores may be 0.7 or less. When the coefficient of variation in the diameters of the open pores is 0.7 or less, the number of open pores having an abnormally large diameter is reduced, so particles generated from the insides of the open pores can be further reduced.

Additionally, the area ratio of the open pores may be 0.10% or less. The smaller the number of open pores, the higher the corrosion resistance. In particular, when the area ratio is 0.05% or less, the corrosion resistance of the plasma processing device member 2a is increased.

Additionally, the mean crystal particle size may be 3μm or more and 8μm or less. When the mean crystal particle size is 3μm or more, the thermal conductivity of the plasma processing device member 2a increases, and the soaking of the plasma processing device member 2a increases. On the other hand, when the mean crystal particle size is 8μm or less, the generation of abnormally grown crystal particles that lower the strength of the yttrium oxide sintered body can be suppressed, so the thermal shock resistance of the plasma processing device member 2a can be improved and the mechanical strength can be increased.

The average of the diameters of open pores, the coefficient of variation in the diameters of open pores, and the area ratio of open pores, other than the distance between the centers of gravity, are measured by using an image analysis software “Win ROOF (Ver.6.1.3)” (manufactured by Mitani Corporation) under the conditions where a magnification is 200 times, a measurement area per measurement is 7.1066×10⁵μm², and an equivalent circle diameter threshold is 0.8μm. Then, by performing this measurement at four locations, the average of the diameters of open pores, the coefficient of variation, and the area ratio can be determined.

The respective kurtoses Ku of the distances between the centers of gravity and the diameters of the open pores may be determined by using a function Kurt provided in Excel (registered trademark, Microsoft Corporation).

The mean crystal particle size can be determined by measuring an area of the surface of the sintered body, having 112μm of horizontal length and 80μm of vertical length, with the use of a scanning electron microscope at a magnification of 1000 times, in which four straight lines having the same length are drawn in the area and the number of crystals existing on the four straight lines is divided by the total length of these straight lines. Herein, the length per straight line may be 20μm. When the surface has a grilled skin and it is difficult to identify grain boundaries and to measure the mean crystal particle size, it is good to measure a polished surface of the sintered body, the polished surface being obtained by polishing the surface until the arithmetic average roughness Ra becomes 0.4μm or less followed by being subjected to thermal etching within a temperature range lower than the sintering temperature by 50 to 100° C.

Next, one example of a method for manufacturing the plasma processing device member 2a of the present embodiment will be described.

First, powder mainly containing yttrium oxide, wax, a dispersant, and a plasticizer are provided.

Based on 100 parts by mass of powder mainly containing yttrium oxide having a purity of 99.9% (hereinafter referred to as yttrium oxide powder), the content of the wax is set to 13 parts by mass or more and 14 parts by mass or less, the content of the dispersant is set to 0.4 parts by mass or more and 0.5 parts by mass or less, and the content of the plasticizer is set to 1.4 parts by mass or more and 1.5 parts by mass or less.

The yttrium oxide powder, the wax, the dispersant, and the plasticizer, all of which are heated to 90° C. or higher, are put in a resin container. At this time, the wax, the dispersant, and the plasticizer are liquid.

Herein, in order to obtain a sintered body having the kurtosis of the distances between the centers of gravity of open pores of 0 or more, it is good to heat the yttrium oxide powder, the wax, the dispersant, and the plasticizer to 90° C. or higher and 140° C. or lower and to put in a resin container.

Next, the container is set in a stirrer to be subjected to rotation-and-revolution for 3 minutes (rotation-and-revolution kneading process), whereby the yttrium oxide powder, the wax, the dispersant, and the plasticizer are stirred to obtain a slurry.

Herein, in order to obtain a sintered body having a mean crystal particle size of 3μm or more and 8μm or less, the mean particle size (D₅₀) of the yttrium oxide powder after the rotation-and-revolution kneading process should be, for example, 0.7μm or more and 2μm or less by adjusting the particle size of the yttrium oxide powder that is a raw material.

Then, a syringe is filled with the obtained slurry, so that the slurry is subjected to a defaming process by subjecting the syringe to rotation-and-revolution for 1 minute with the use of a defoaming jig.

Herein, in order to obtain a sintered body having the kurtosis of the diameters of open pores of 0 or more, the slurry may be preheated at 120° C. or higher and 180° C. or lower before the defoaming process.

Next, the syringe filled with the defoamed slurry is attached to an injection molding machine such that injection molding is performed in a state in which the temperature of the slurry is maintained at 90° C. or higher, whereby a cylindrical molded body is obtained. Herein, a flow path of the injection molding machine, through which the slurry passes, may also be maintained at 90° C. or higher.

A cylindrical sintered body can be obtained by sequentially degreasing and sintering the obtained molded body. Herein, the sintering atmosphere may be an air atmosphere, the sintering temperature may be 1600° C. or higher and 1800° C. or lower, and the holding time may be 2 hours or more and 4 hours or less.

Additionally, in order to obtain a sintered body having the average of the diameters of open pores of 2.5μm or less, the sintering atmosphere may be an air atmosphere, the sintering temperature may be 1620° C. or higher and 1800° C. or lower, and the holding time may be 3 hours or more and 4 hours or less.

Additionally, in order to obtain a sintered body having the coefficient of variation in the diameters of open pores of 0.7 or less, the sintering atmosphere may be an air atmosphere, the sintering temperature may be 1620° C. or higher and 1800° C. or lower, and the holding time may be 3.5 hours or more and 4 hours or less.

Additionally, in order to obtain a sintered body having the area ratio of open pores of 0.10% or less, the sintering atmosphere may be an air atmosphere, the sintering temperature may be 1700° C. or higher and 1800° C. or lower, and the holding time may be 3 hours or more and 4 hours or less.

The present disclosure is not limited to the above embodiments, and various changes, improvements, combinations, and the like can be made without departing from the gist of the present disclosure.

In the example shown in FIG. 1, the plasma processing device member 2a is shown as the gas passage pipe 2a that is arranged in the chamber 1 and generates stable plasma from the plasma generating gas G. However, the member 2a may be a member that supplies the plasma generating gas G to the chamber 1, or a member that discharges the plasma generating gas G from the chamber 1.

### EXAMPLE 1

Yttrium oxide powder having a purity of 99.99% by mass, wax, a dispersant, and a plasticizer were heated to 90° C., and then they were put in a resin container and mixed. Next, the container was placed at a predetermined position of a stirrer, so that the container was subjected to rotation-and-revolution (rotation-and-revolution kneading process) for 3 minutes, whereby a slurry was obtained.

Herein, the content of the wax was set to 13.5 parts by mass, the content of the dispersant was set to 0.45 parts by mass, and the content of the plasticizer was set to 1.45 parts by mass, based on 100 parts by mass of the yttrium oxide powder.

Then, a syringe was filled with the obtained slurry, and a defoaming process was performed on the slurry by using a defoaming jig, while the syringe was being subjected to rotation-and-revolution for 1 minute.

The syringe was attached to an injection molding machine, and injection molding was performed in a state in which the temperature of the slurry was maintained at 90° C. or higher, whereby a cylindrical molded body was obtained. At this time, a slurry flow path of the injection molding machine was also maintained at 90° C. or higher.

A cylindrical yttrium oxide sintered body was obtained by sequentially degreasing and sintering the molded body. Herein, the sintering atmosphere was set to an air atmosphere, and the sintering temperature and holding time were set as shown in Table 1.

Sample Nos. 1 to 11, which are cylindrical sintered bodies, have an inner peripheral surface as sintered, and some of the samples were caused to have a half-cylindrical shape by polishing from the outer periphery side.

As a result of examining each sample with an X-ray diffractometer using CuKα rays, the presence of yttrium oxide was confirmed. Additionally, as a result of measuring the content of each metal element with an ICP (Inductively Coupled Plasma) emission spectrometer, it has been found that the content of yttrium was the highest in every sample, which was 99.99% by mass or more in terms of yttrium oxide.

Then, in order to determine the average of the distances between the centers of gravity of open pores, an area of the inner peripheral surface of the sintered body, having 1.1 mm of horizontal length and 0.8 mm of vertical length, was observed at a magnification of 100 times by applying a method called the center-of-gravity distance method of the image analysis software “A image-kun (Ver2.52)” (registered trademark, manufactured by Asahi Kasei Engineering Corporation), whereby the distance between the centers of gravity of the adjacent open pores was obtained, those values being shown in Table 1.

Additionally, the average of the diameters of open pores, the coefficient of variation, and the area ratio were determined by measuring at four locations and using an image analysis software “Win ROOF (Ver.6.1.3)” (manufactured by Mitani Corporation) under the conditions in which a magnification was 200 times, a measurement area per measurement was 7.1066×10⁵ μm², and an equivalent circle diameter threshold was 0.8μm, the results being shown in Table 1.

Next, the corrosion resistance of each sample to plasma was examined. Specifically, the sample was placed in a RIE (Reactive Ion Etching) apparatus to be exposed to plasma generated from a mixed gas containing CF₄ (40 sccm) and O₂ (10 sccm) for 30 hours, so that a mass decrease rate after the exposure to plasma was calculated. A relative value, when the mass decrease rate of the sample No.1, which is a comparative example, was set to 1, is shown in Table 1. Herein, the output of the high-frequency power supply of the RIE apparatus was set to 1000 W, and the frequency to 13.56 MHz.

TABLE 1

| | | | | Average of the | Coefficient of | Area ratio | |
|---|---|---|---|---|---|---|---|
| | Sinteriing | Holding | | diameters of | variation in the | of the | Mass |
| Sample | temperature | time | L1 | open pores | diameters of | open pores | derease |
| No. | (° C.) | (hours) | (μm) | (μm) | open pores | (%) | rates |
| 1 | 1550 | 3 | 45 | 3.1 | 1 | 0.735 | 1.000 |
| 2 | 1600 | 3 | 50 | 2.70 | 0.9 | 0.155 | 0.783 |
| 3 | 1620 | 3 | 71 | 2.50 | 0.8 | 0.135 | 0.717 |
| 4 | 1620 | 3.5 | 70 | 2.50 | 0.7 | 0.115 | 0.707 |
| 5 | 1620 | 4 | 68 | 2.49 | 0.6 | 0.105 | 0.696 |
| 6 | 1650 | 3 | 98 | 2.04 | 0.8 | 0.105 | 0.674 |
| 7 | 1700 | 3 | 145 | 1.43 | 0.8 | 0.075 | 0.554 |
| 8 | 1750 | 3 | 194 | 1.20 | 0.8 | 0.065 | 0.543 |
| 9 | 1800 | 3 | 240 | 0.90 | 0.8 | 0.055 | 0.533 |
| 10 | 1800 | 3.5 | 240 | 0.81 | 0.7 | 0.045 | 0.511 |

The mass decrease rates of the sample Nos. 2 to 10 each having L1 of 50μm or more, after the exposure to plasma, are smaller than the sample No. 1 having L1 of less than 50μm, as shown in Table 1, and hence it has been found that the corrosion resistances of them to plasma are high.

Further, it has been found that, of the sample Nos. 2 to 10, the sample Nos. 3 to 10, each having the average of the diameters of open pores of 2.5μm or less, have a higher corrosion resistance to plasma.

Furthermore, the samples Nos. 4 to 10, each having the coefficient of variation in the diameters of open pores of 0.7 or less, had a high corrosion resistance to plasma.

Still furthermore, it has been found that the sample

Nos. 7 to 10, each having the area ratio of open pores of 0.10% or less, have a high corrosion resistance to plasma. Still furthermore, it has been found that the sample No. 10, having the area ratio of open pores of 0.05% or less, have a higher resistance to plasma.

Herein, the mean crystal particle sizes of the sample Nos. 1 to 10 were within the range of 3μm to 8μm, inclusive.

### DESCRIPTION OF THE REFERENCE NUMERAL

1: Chamber

2: Upper electrode

2a: Plasma processing device member, gas passage pipe

2b: Electrode plate

2c: Diffusion portion

2d: Introduction hole

2e: Holding member

2f: Shower plate

3: Lower electrode

4: High-frequency power supply

5: Electrostatic chuck

10: Plasma processing device

1. A plasma processing device member that is made of an yttrium oxide sintered body containing 98% by mass or more of yttrium oxide and having a plurality of open pores, wherein
an average of distances L1 between centers of gravity of the open pores adjacent to each other is 50μm or more.

2. The plasma processing device member according to claim 1, wherein a kurtosis of the distances between the centers of gravity of the open pores is 0 or more.

3. The plasma processing device member according to claim 1, wherein an average of diameters of the open pores is 2.5μm or less.

4. The plasma processing device member according to claim 3, wherein a kurtosis of the diameters of the open pores is 0 or more.

5. The plasma processing device member according to claim 3, wherein a coefficient of variation in the diameters of the open pores is 0.7 or less.

6. The plasma processing device member according to claim 1, wherein an area ratio of the open pores is 0.10% or less.

7. The plasma processing device member according to claim 1, wherein a mean crystal particle size is 3μm or more and 8μm or less.

8. A plasma processing device comprising:
the plasma processing device member according to claim 1; and
a plasma generator.
